(19) United States
(12) Patent Application Publication
(10) Pub. No.: US 2007/0057932 A1
(43) Pub. Date: Mar. 15, 2007

(54) Flat panel display and organic light emitting display

(76) Inventors: Hyun Soo Shin, Yongin-si (KR); Jae Kyeong Jeong, Yongin-si (KR); Yeon Gon Mo, Yongin-si (KR); Dong Un Jin, Yongin-si (KR)

Correspondence Address: Robert E. Bushnell, Suite 300, 1522 K Street, N.W., Washington, DC, 20005, US

(21) Appl. No.: 11/519,928

(22) Filed: Sep. 13, 2006

(30) Foreign Application Priority Data
Sep. 13, 2005 (KR) 2005-85412

(51) Int. Cl. G09G 5/00

(52) U.S. Cl. 345/204

(57) ABSTRACT

The present invention relates to a flat panel display and an organic light emitting display which maintains an opaque state depending on a user's desired time point or an established time point, while maintaining a transparent state at ordinary times, by forming a transparent two side emission panel and a control unit on the lower portion of the transparent two side emission panel, enabling to freely display an image in two side or one side. A flat panel display (FPD) of the present invention is constructed with a transparent two side emission panel and a control unit provided on at least one side of the transparent two side emission panel to control transmission of light. The control unit controlling an array of liquid crystal layers depending on voltage applied to the liquid crystal layers and transmission of light by a first polarizing member and a second polarizing member. As a result, the present invention maintains an opaque state depending on a user's desired time point or an established time point, while maintaining a transparent state at ordinary times, enabling to freely display an image in two sides or one side.

### CLAIM OF PRIORITY

This application makes reference to, incorporates the same herein, and claims all benefits accruing under 35 U.S.C. § 119 from an application earlier filed in the Korean Intellectual Property Office on Sep. 13, 2005 and there duly assigned Serial No. 10-2005-0085412.

### BACKGROUND

1. Field of the Invention

The present invention relates to a flat panel display and an organic light emitting display, and more particularly, to a flat panel display and an organic light emitting display which maintains an opaque state depending on a user's desired time point or an established time point, while maintaining a transparent state at ordinary times, by forming a transparent two side emission panel and a control unit on the lower portion of the transparent two side emission panel, freely enabling display of images on either two sides or one side.

2. Description of the Related Art

Demands on personal computers (PC), car navigation systems, personal digital assistants, information communication devices, and combination products of the above have recently increased with the advent of an information oriented society. The above-described products require characteristics of high visibility, wide view angle, and display of moving images at high response speeds. A flat panel display (FPD) is suitable for the above characteristics so that the FPD is spotlighted as a next generation display.

In general, a thin film transistor (TFT) has widely been used as a switching device that operates each pixel in a display device such as an organic light emitting display (OLED) or a liquid crystal display (LCD), etc. Therefore, significant attention is paid to the fabrication of the TFT, and a FPD using more effective TFTs and a method of driving the same are provided.

A contemporary organic light emitting display is typically constructed with a substrate, a buffer layer formed on the substrate, a semiconductor layer including an active layer and an ohmic contact layers formed on a region of the buffer layer, and a gate insulating layer formed on the semiconductor layer. A gate electrode is formed on a region of the gate insulating layer and an interlayer insulating layer is formed on the gate electrode. Source and drain electrodes formed on a region of the interlayer insulating layer are connected to the exposed regions of the ohmic contact layers and a planarization layer is formed on the source and drain electrodes. A first electrode layer formed on a region of the planarization layer is connected to the exposed region of either one of the exposed source and drain electrodes. A pixel defining layer including an aperture that allows exposure of at least a region of the first electrode layer is formed on the first electrode layer and the planarization layer. A emission layer is formed on the aperture and a second electrode layer is formed on the emission layer and the pixel defining layer.

An thin film transistor (TFT) includes the semiconductor layer, the gate electrode, and the source and drain electrodes. Here, the semiconductor layer, the gate electrode, and the source and drain electrodes are made from an opaque material. In particular, the semiconductor layer is made from amorphous silicon or polysilicon. Since these materials are not transparent, when the opaque TFT is used as the switching device of the organic light emitting display, there are limitations on increasing the width of a channel due to the characteristics of the opaque semiconductor layer. Therefore, large current does not flow into the channel so that a high voltage must be applied to the TFT. Therefore, problems have occurred because that the light emitting device of the contemporary organic light emitting display deteriorates and power consumption increases. Also, it is not possible to select either two side emission or front side emission in accordance with a user's desired time point or the brightness of a external region.

### SUMMARY OF THE INVENTION

It is therefore an object of the present invention to provide an improved flat panel display and an organic light emitting display.

Accordingly, in order to solve the problems as above stated, it is another object of the present invention to provide a flat panel display and an organic light emitting display which maintains an opaque state depending on a user's desired time point or an established time point, while maintaining a transparent state at ordinary times by forming a transparent two side emission panel and a control unit on the lower portion of the transparent two side emission panel, thereby freely enabling display of images on either two sides or one side.

In order to achieve the foregoing objects of the present invention, according to one aspect of the present invention, there is provided a flat panel display (FPD) constructed with a transparent two side emission panel, and a control unit provided on at least one side of the transparent two side emission panel to control transmission of light, the control unit controlling an array of liquid crystal layers depending on the voltage applied to the liquid crystal layers and transmission of light by a first polarizing member and a second polarizing member.

Preferably, the control unit is constructed with a first polarizing member connected to a side of the transparent two side emission panel, a first substrate connected to the first polarizing member, a first transparent electrode connected to the first substrate, a liquid crystal layer connected to the first transparent electrode, a second transparent electrode connected to the liquid crystal layer, a second substrate connected to the second transparent electrode, and a second polarizing member connected to the lower portion of the second substrate.

According to another aspect of the present invention, there is provided an organic light emitting display constructed with an organic light emitting display unit including at least one organic light emitting element formed on one side of a transparent substrate, and a control unit formed on the other side of the organic light emitting display unit to control intensity of light of the organic light emitting display unit, the control unit controlling an array of liquid crystal layers depending on voltage applied to the liquid crystal layers and transmission of light by a first polarizing member and a second polarizing member.

Preferably, the control unit is constructed with a first polarizing member connected to a region of the organic light emitting element, a first substrate connected to the first polarizing member, a first transparent electrode connected to the first substrate, a liquid crystal layer connected to the first transparent electrode, a second transparent electrode connected to the lower portion of the liquid crystal layer, a second substrate connected to the second transparent electrode, and a second polarizing member connected to the second substrate. The control unit is further constructed with a controller that applies a power source to the first transparent electrode and the second transparent electrode.

The organic light emitting display unit is constructed with at least one transparent thin film transistor driving the organic light emitting element, wherein the transparent thin film transistor is constructed with a transparent semiconductor layer, a gate electrode, and source and drain electrodes, which are formed on the transparent substrate, a band gap of the transparent semiconductor layer is made from wide band semiconductor substances larger than 3.0 eV, and the wide band semiconductor substances are made from ZnO, ZnSnO, GaSnO, GaN or SiC.

### BRIEF DESCRIPTION OF THE DRAWINGS

A more complete appreciation of this invention, an many of the attendant advantages thereof, will be readily apparent as the same becomes better understood by reference to the following detailed description when considered in conjunction with the accompanying drawings in which like reference symbols indicate the same or similar components, wherein:

FIG. 1 is a schematic cross-sectional view illustrating a contemporary organic light emitting display (OLED);

FIG. 2 is a schematic cross-sectional view illustrating an organic light emitting display constructed as a first embodiment of the principles of the present invention;

FIG. 3 is a schematic cross-sectional view illustrating an organic light emitting display constructed as a second embodiment of the principles of the present invention;

FIG. 4 is a schematic cross-sectional view illustrating a state that voltage is applied to a first electrode in the second embodiment of the principles of the present invention;

FIG. 5 is a schematic cross-sectional view illustrating a state that voltage is applied to a second electrode in the second embodiment of the principles of the present invention;

FIG. 6 is a schematic cross-sectional view illustrating a state that voltage is not applied to an organic light emitting display according to a third embodiment of the principles of the present invention;

FIG. 7 is a schematic cross-sectional view illustrating a state that a voltage is applied to the organic light emitting display constructed as the third embodiment of the principles of the present invention; and

FIG. 8 is a schematic cross-sectional view illustrating another state that a voltage is applied to the organic light emitting display constructed as the third embodiment of the principles of the present invention.

### DETAILED DESCRIPTION OF THE PREFERRED EMBODIMENTS

Hereinafter, among the contemporary FPDs, an organic light emitting display will be described in detail with reference to the attached drawings.

FIG. 1 is a schematic sectional view of a contemporary organic light emitting display.

Referring to FIG. 1, a contemporary organic light emitting display 120 is constructed with a substrate 100, a buffer layer 101 formed on substrate 100, a semiconductor layer 102 including an active layer 102a and ohmic contact layers 102b formed on a region of buffer layer 101, and a gate insulating layer 103 formed on semiconductor layer 102. A gate electrode 104 is formed on a region of gate insulating layer 103 and an interlayer insulating layer 105 is formed on gate electrode 104. Source and drain electrodes 106a and 106b formed on a region of interlayer insulating layer 105 are connected to the exposed regions of ohmic contact layers 102b and a planarization layer 107 is formed on source and drain electrodes 106a and 106b. A first electrode layer 108 formed on a region of planarization layer 107 is connected to the exposed regions of either one of the exposed source and drain electrodes 106a and 106b. A pixel defining layer 109 including an aperture 162 that allows the exposure of at least a region of first electrode layer 108 is formed on first electrode layer 108 and planarization layer 107. A emission layer 110 is formed on aperture 162 and a second electrode layer 111 is formed on emission layer 110 and pixel defining layer 109.

Semiconductor layer 102, gate electrode 104, and source and drain electrodes 106a and 106b integrally form thin film transistor (TFT) 113. Here, semiconductor layer 102, gate electrode 104, and source and drain electrodes 106a and 106b are made from opaque materials. In particular, semiconductor layer 102 is made from amorphous silicon or polysilicon. These materials are not transparent; however, when an opaque TFT 113 is used as the switching device of organic light emitting display 120, there are limitations on increases in the width of a channel due to the characteristics of the opaque semiconductor layer 102. Therefore, large current does not flow into the channel so that a high voltage must be applied to TFT 113. Therefore, there are problems that the light emitting device of the contemporary organic light emitting display deteriorates and power consumption increases. Also, it is not possible to select either two side emission or front side emission in accordance with a user's desired time point or the brightness of a external region.

Hereinafter, a flat panel display (FPD) and a method of driving the same according to preferred embodiments of the principles of present invention will be described with reference to the attached drawings.

According to the present invention, in order to simplify description, the word ‘transparent’ comprises the meaning of ‘transparent or transmissive’. Also, according to the present invention, for the sake of convenience, a control unit connected to an emission panel using an organic light emitting display (OLED) is described. The present invention, however, can be applied to a liquid crystal display (LCD), a field emission display (FED), a plasma display panel (PDP), an electro-luminescent display (ELD), and a vacuum fluorescent display (VFD).

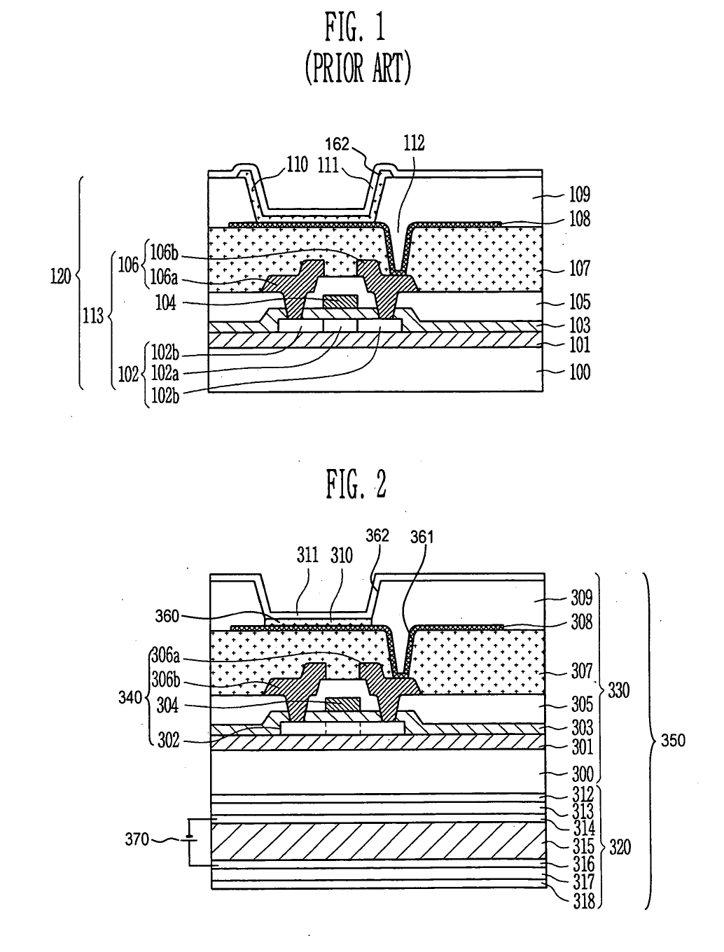

FIG. 2 is a schematic sectional view illustrating an organic light emitting display constructed as a first embodiment of the principles of the present invention.

Referring to FIG. 2, organic light emitting display 350 is constructed with a display unit 330 including at least one organic light emitting diode 360, a thin film transistor 340 formed on a region of a first transparent substrate 300, and a control unit 320 formed on the lower portion of display unit 330 to control intensity of light of display unit 330.

Hereinafter, control unit 320 will be described in more detail.

In control unit 320, a first substrate 313 and a second substrate 317 of control unit 320 are arranged to be opposite to each other; a first transparent electrode 314 and a second transparent electrode 316 are formed in the inner sides of first substrate 313 and second substrate 317, respectively; a liquid crystal layer 315, which is a light shielding layer, is interposed between first transparent electrode 314 and second transparent electrode 316; and a first polarizing plate 312 and a second polarizing plate 318 are positioned in outer sides of first substrate 313 and second substrate 317, respectively.

Also, control unit 320 is further constructed with a controller 370 applying voltage to first transparent electrode 314 and second transparent electrode 316, and controller 370 can be manually driven or automatically controlled by a photosensor (not shown).

Liquid crystal layer 315 can shield or transmit light, when controller 370 applies voltage to first transparent electrode 314 and second transparent electrode 316.

For example, when control unit 320 is made from twisted nematics (TN), control unit 320 varies an array of liquid crystal molecules in liquid crystal layer 315 depending on the voltage applied to first transparent electrode 314 and second transparent electrode 316. In other words, the array of liquid crystal molecules in liquid crystal layer 315 become 90° twisted and horizontally arranged to a substrate, when the voltage is off; and the array of liquid crystal molecules in liquid crystal layer 315 is untwisted and vertically arranged to a substrate, when the voltage is on.

Accordingly, when the voltage is off, only a portion of a light source, which coincides with a first polarization axis of first polarizing plate 312, passes through first polarizing plate 312. The first linearly polarized light passes through the 90° twisted liquid crystal layer 315 so that it becomes a second linearly polarized light, which is in a polarization state that coincides with a second transmitting axis of second polarizing plate 318, and passes through a substrate, so that it is displayed as white on a screen.

When the voltage is on, only a portion of the light source, which coincides with a first polarization axis of first polarizing plate 312, passes through first polarizing plate 312. Although the first linearly polarized light passes through liquid crystal molecules in liquid crystal layer 315 vertically arranged to a substrate, the first linearly polarized light is shielded by second polarizing plate 318, so that it is displayed as black on a screen.

As described above, first polarizing plate 312 and second polarizing plate 318 in control unit 320 can display gray between black and white by controlling the intensity of a transmitting light depending upon the degree of revolution of the polarization axis of the transmitting light while the light passes through a liquid crystal layer 315.

Hereinafter, display unit 330 will be described in more detail.

Display unit 330 is formed on control unit 320. Display unit 330 is constructed with a substrate 300, a buffer layer 301 formed on substrate 300, a transparent semiconductor layer 302 formed in a predetermined pattern on, buffer layer 301, a gate insulating layer 303 formed on transparent semiconductor layer 302, a gate electrode 304 formed on gate insulating layer 303 and patterned to correspond to transparent semiconductor layer 302, an interlayer insulating layer 305 formed on gate electrode 304, a planarization layer 307 formed on source and drain electrodes 306a and 306b and electrically connected to transparent semiconductor layer 302 via a contact hole (not shown) formed in gate insulating layer 303 and interlayer insulating layer 305, a third electrode layer 308 formed on a region of planarization layer 307 and connected to either one of source and drain electrodes 306a and 306b, a pixel defining film 309 formed on third electrode layer 308 and having an aperture 362 that at least partially exposes third electrode layer 308, a emission layer 310 formed on a region of pixel defining film 309 and aperture 362, and a fourth electrode layer 311 formed on the upper portion of emission layer 310.

Transparent substrate 300, for example, may be made from insulating materials such as glass, plastic, sapphire, silicon or synthetic resins. It is most preferable that transparent substrate 300 is formed as a flexible thin film.

Buffer layer 301 is formed on substrate 300. Buffer layer 301 is made from a nitride film, an oxide film or transparent insulating materials, but is not limited to these materials.

Semiconductor layer 302 is made from wide band semiconductor substances whose band gap is approximately 3.0 eV or more and which have transparency. For example, semiconductor layer 302 is made from at least one selected from the group of oxides such as ZnO, ZnSnO, CdSnO, GaSnO, TlSnO, InGaZnO, CuAlO, SrCuO, and LaCuOS, nitrides such as GaN, InGaN, AlGaN, and InGaAlN, and carbides such as SiC and diamond.

Gate insulating layer 303 is formed on transparent semiconductor layer 302, and insulates transparent semiconductor layer 302 and gate electrode 304. Gate insulating layer 303 is made from an oxide film, a nitride film or transparent insulating materials, but is not limited to these materials.

Gate electrode 304 is formed on gate insulating layer 303 and is formed on the upper portion of the channel region (not shown) of transparent semiconductor layer 302 in a pattern. And, gate electrode 304 and source and drain electrodes 306a and 306b are made from metals having good conductivity and transparency such as indium tin oxide (ITO), indium zinc oxide (IZO), and indium tin zinc oxide (ITZO) and translucent metals, but are not limited to these materials.

Interlayer insulating layer 305 are formed on gate electrode 304 and made from the same substances as the one from which gate insulating layer 303 is made.

And, source and drain electrodes 306 and 306b are formed on interlayer insulating layer 305, and are electrically connected to both sides of transparent semiconductor layer 302 via a contact hole formed on gate insulating layer 303 and interlayer insulating layer 305. Here, source and drain electrodes 306a and 306 are made from the same substances as the one from which gate electrode 304 is made.

Planarization layer 307 is formed on the transparent thin film transistor 340 and is made from a nitride film, an oxide film or transparent insulating materials, but is not limited to these materials. A via hole 361 is formed in planarization layer 307 by etching a region of planarization layer 307. Third electrode layer 308 is electrically connected to either one of source and drain electrodes 306a and 306b through via hole 361 formed in planarization layer 307.

Also, pixel defining film 309 is formed on third electrode layer 308, and has an aperture 362 that at least partially exposes third electrode layer 308. And, emission layer 310 is formed on a region of pixel defining layer 309 and aperture 362, and can further include some of a hole injecting layer, a hole transporting layer, an electron injecting layer, and an electron transporting layer. Such emission layer 310 emits light when holes and electrons injected from third electrode layer 308 and fourth electrode layer 311, respectively, are combined.

Fourth electrode layer 311 is formed on emission layer 310 and pixel defining film 309, and third electrode layer and fourth electrode layer 310 are made from the same substances as the one from which gate electrode 304 is made.

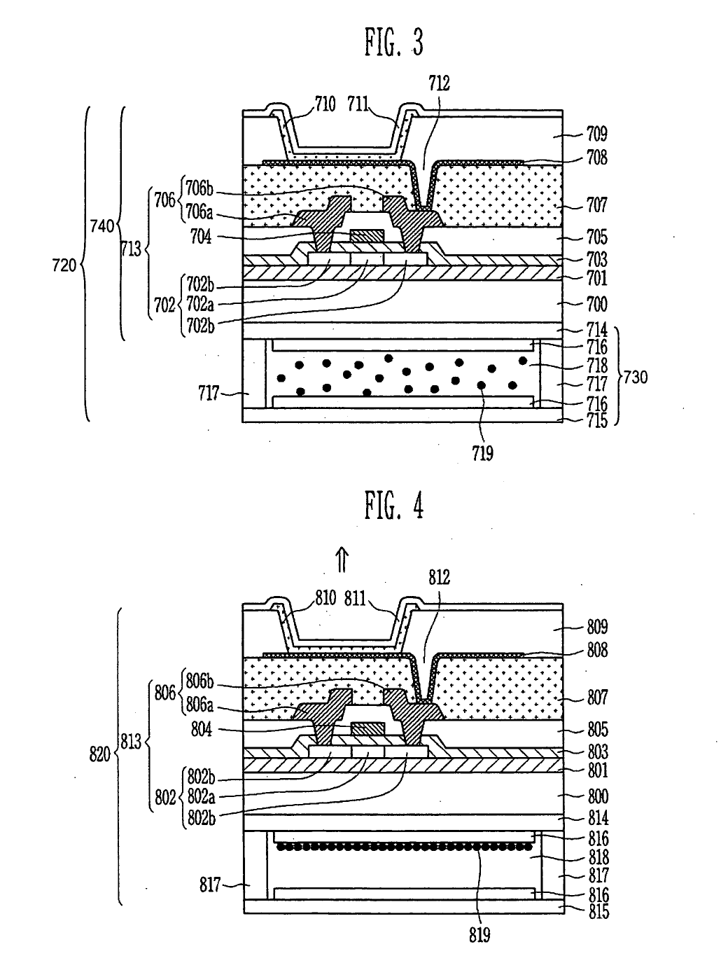

FIG. 3 is a schematic sectional view illustrating an organic light emitting display constructed as a second embodiment of the principles of the present invention.

As shown in FIG. 3, an organic light emitting display 720 according to the principles of the present invention is constructed with at least one transparent thin film transistor 713 and an emission unit 710 on substrate 700 of organic light emitting display 720.

And, the lower portion of substrate 700 is attached to an electrophoretic device 730 that is a control unit. Electrophoretic device 730 is a non-emission type display device, including an electrophoretic display device using a known electrophoretic phenomenon. According to the electrophoretic phenomenon, when an electric field is applied to a solution obtained by dispersing charged particles in a solvent, the charged particles being dispersed are naturally electrophoreticed by Coulomb force. When the solution contains the particles in the form of a capsule and electric shock is applied to the solution, the particles move to perform electrical display.

Electrophoretic device 730 under substrate 700 according to the present invention is constructed with a first transparent substrate 714 connected to one side of a transparent two side emission panel 740 and a second transparent substrate 715 spaced apart from first transparent substrate 714 and facing first transparent substrate 714. A pair of first transparent electrodes 716, respectively, are mounted on the sides of first transparent substrate 714 and second transparent substrate 715 that face each other, and a pair of second transparent electrodes 717, respectively, are mounted on the ends of first transparent substrate 714 and second transparent substrate 715. A solvent 718 into which charged particles 719 are dispersed, serving as a light shielding layer, is filled between first transparent substrate 714 and second transparent substrate 715.

First transparent electrode 716 may be entirely formed on the internal side of first transparent substrate 714 or second transparent substrate 715, or may be divided into a plurality of pieces.

A pair of second transparent electrodes 717 are formed on both ends of the internal side of first transparent substrate 714 and second transparent substrate 715. Although not shown in the drawing, spacers may be further provided outside second transparent electrodes 717 so that first transparent substrate 714 and second transparent substrate 715 are spaced apart from each other.

Solvent 718 is filled between first transparent substrate 714 and second transparent substrate 715 and at least one charged particle 719 is dispersed into solvent 718. Charged particles 719 are black and are made from materials having satisfactory charged characteristic in positive polar or negative polar of solvent 718. For example, charged particles 719 are made from inorganic pigment, organic pigment, carbon black, or resin containing the material. Also, solvent 718 has insulation property that solvent 718 does not react with charged particles 719 and is made from a transparent non-polar solvent such as isoparaffin, silicon oil, xylene, and toluene.

A charge control agent for controlling charge of charged particles 719 to stabilize the charge of charged particles 719 may be added to solvent 718 or charged particles 719. Succinimide, metal complex of monoazo dye, salicylic acid, and organic silicon quaternary ammonium salt, and nigrosine compound are used as the charge control agent. A dispersion agent for preventing charged particles 719 from being cohered to remain dispersed may be further added to solvent 718. Polyvalent metal salt phosphate such as calcium phosphate and magnesium phosphate, carbonate such as calcium carbonate, inorganic salt, inorganic oxide, and organic polymer material are used as the dispersion agent.

There are no limitations on the combination between solvent 718 and charged particles 719. Solvent 718 and charged particles 719, however, are preferably combined with each other at the same ratio in order to prevent charged particles 719 from sinking due to gravity.

Also, a system control unit (not shown) for applying a voltage to first transparent electrode 716 or second transparent electrode 717 is included so that the voltage is selectively applied to first transparent electrode 716 and second transparent electrode 717 by the switch provided in the system control unit.

The thickness of electrophoretic device 730 attached under substrate 200 is between approximately 50 μm and approximately 500 μm.

Solvent 718 or charged particles 719 serve as a light shielding layer for shielding or transmitting light depending on the voltage applied to first transparent electrode 716 and second transparent electrode 717. Therefore, substances interposed between first transparent electrode 716 and second transparent electrode 717 are not limited to solvent 718 or the charged particles 719, and any substances capable of being switch-driven by first transparent electrode 716 and second transparent electrode 717 can be used. The substance satisfying conditions described above includes polymer dispersed liquid crystal (PDLC), for example.

F PDLC is not applied with voltage, it is arranged in irregular direction to cause scattering of a light at an interface between two medium with different indexes of refraction. And, if liquid crystal molecule is applied with voltage, the PDLC is uniformly arranged in a regular direction. As a result, the light can be shielded or transmitted by selectively applying voltage to first transparent electrode 716 and second transparent electrode 717.

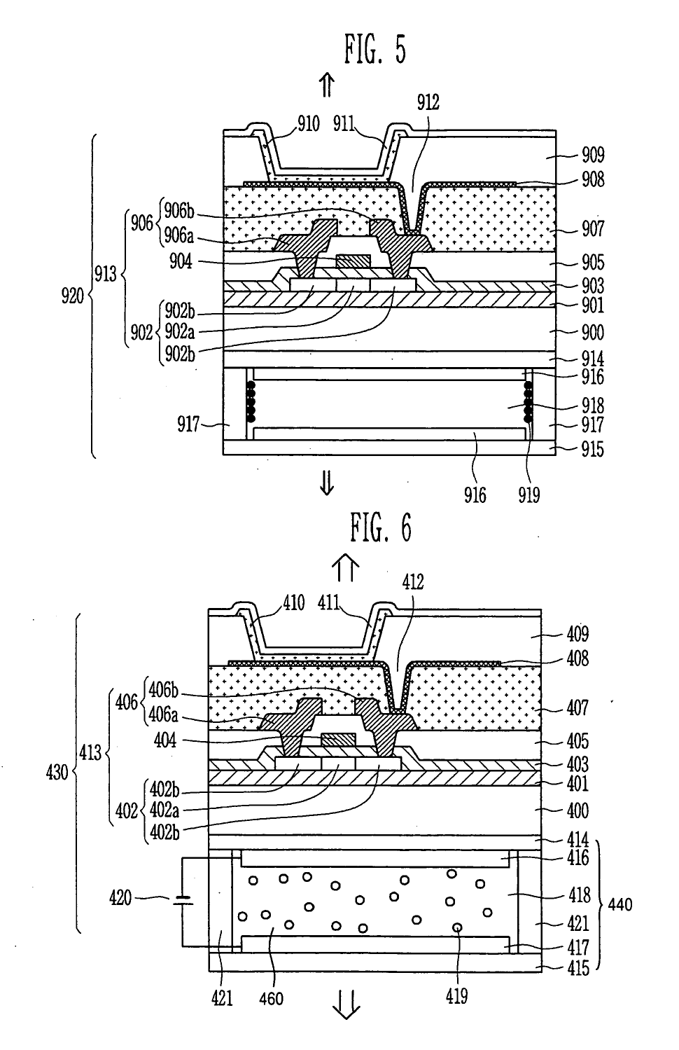

FIGS. 4 and 5 are schematic sectional views illustrating a method of driving the OLED illustrated in FIG. 3. For the sake of convenience, detailed description of the same elements as those of FIG. 3 will be omitted. In particular, detailed description of transparent TFT 813 formed on substrate 800 and the material of transparent TFT 813 will be omitted.

FIG. 4 is a schematic sectional view illustrating a state that a voltage is applied to first electrode 816 according to a second embodiment of the principles of the present invention.

Referring to FIG. 4, when charged particles 819 have positive (+) charges, a negative (−) voltage is applied to first transparent electrode 816. When the negative (−) voltage is applied to first transparent electrode 816, charged particles 819 having the positive (+) charges are adsorbed to first transparent electrode 816. Since charged particles 819 are black, the rear side of OLED 820 from which light is emitted operates as a black matrix by the charged particles so that OLED 820 constructed according to the principles of the present invention emits light from the front side.

Also, when charged particles 819 have negative (−) charges, a positive (+) voltage is applied to first transparent electrode 816. When the positive (+) voltage is applied to first transparent electrode 816, charged particles 819 having the negative (−) charges are adsorbed to first transparent electrode 816. Since charged particles 819 are black, the rear side of OLED 820 from which light is emitted operates as a black matrix so that OLED 820 constructed according to the principles of the present invention emits light from the front side.

FIG. 5 is a schematic sectional view illustrating a state that a voltage is applied to a second electrode according to the second embodiment of the present invention.

Referring to FIG. 5, when charged particles 919 have the positive (+) charges, the negative (−) voltage is applied to second transparent electrodes 917 in the form of barrier ribs that contact first transparent substrate 914 and second transparent substrate 915. Since the negative (−) voltage is applied to second transparent electrode 917, charged particles 919 having the positive (+) charges are adsorbed to second transparent electrodes 917 in the form of barrier ribs. Therefore, the rear side of an OLED 920 constructed according to the principles of the present invention from which light is emitted becomes transparent so that OLED 920 emits light from two sides.

When charged particles 919 have the negative (−) charges, the positive (+) voltage is applied to second transparent electrodes 917 in the form of barrier ribs that contact first transparent substrate 914 and second transparent substrate 915. Since the positive (+) voltage is applied to second transparent electrode 917, charged particles 919 having the negative (−) charges are adsorbed to second transparent electrodes 917 in the form of barrier ribs. Therefore, the rear side of OLED 920 constructed according to the principles of the present invention from which light is emitted becomes transparent so that the OLED 920 emits light from two sides.

According to the flat panel display of the present invention, the voltage applied to the first transparent electrode or the second transparent electrode is controlled, thereby making it possible to freely display an image in front side emission and two side emission at a user's desired time point.

FIG. 6 is a schematic sectional view illustrating a state that voltage is not applied to an organic light emitting display according to a third embodiment of the present invention;

As shown in FIG. 6, on a substrate 400 of the OLED 420 constructed according to the principles of the present invention are at least one transparent TFT 413 and a emission unit 410.

The lower portion of substrate 400 is attached with an electrochromic device 440 that is a control unit. In general, electrochromism is a phenomenon reversibly making electrolytic oxidizing and reducing reactions and reversibly making coloring and decoloring, when voltage is applied. The electrochromic device using the phenomenon has been used as a light amount controller (for example, a mirror such as an antiglare mirror or a light control glass, or a brightness controlling element such as an organic light emitting diode) or a display element for numeral display using a segment or an electrochromic display. The electrochromic device can mainly be classified into a solution type and a complete solid type in accordance with a material type of an electrochromic layer constituting the electrochromic device.

In electrochromic device 440 attached to the lower portion of substrate 400 according to the principles of the present invention, first transparent substrate 414 and second transparent substrate 415 are formed to be opposite to each other on other side of substrate 400 and spaced apart from each other. Although not shown in the drawing, spacers may be formed between first transparent substrate 414 and second transparent substrate 415 to allow first transparent substrate 414 and second transparent substrate 415 to have a distance. First transparent substrate 414 and second transparent substrate 415 may be made from a transparent glass substrate such as quartz glass plate and a white board glass plate, but are not limited to there materials. For example, first transparent substrate 414 and second transparent substrate 415 may use ester such as polyethylenenaphthalate and polyethyleneterephthalate, cellulose ester such as polyamide, polycarbonate, and cellulose acetate, fluoropolymer such as polyvinylidene fluoride and polytetrafluoroethylenecohexafluoropropylene, polyether such as polyoxymethylene, polyolefin such as polyether, polyacetal, polystyrene, polyethylene, polypropylene, and methylpentenepolymer, and polyimide such as polyimideamide and polyetherimide.

First transparent electrode 416 and second transparent electrode 417 are formed on the internal sides of first transparent substrate 414 and second transparent substrate 415, respectively. First transparent electrode 416 and second transparent electrode 417 may be made from a film of ITO, SnO, InO, ZnO, and the similar materials. First and second transparent electrode 416 and 417 attached to first transparent substrate 414 and second transparent substrate 415, respectively, can be formed by known methods such as a deposition method, an ion plating method, and a sputtering method.

Also, electrochromic layer 460 filled with an electrolyte 418 containing a coloring agent 419, which is a light shielding layer, is formed between first transparent electrode 416 and second transparent electrode 417. Electrochromic layer 460 can be made from electrolyte obtained by dissolving, for example, cathode compound such as viologen derivative, and anode compound consisting of metallocene(M(C₅ G₅)₂) or its derivative, with non-aqueous solvent.

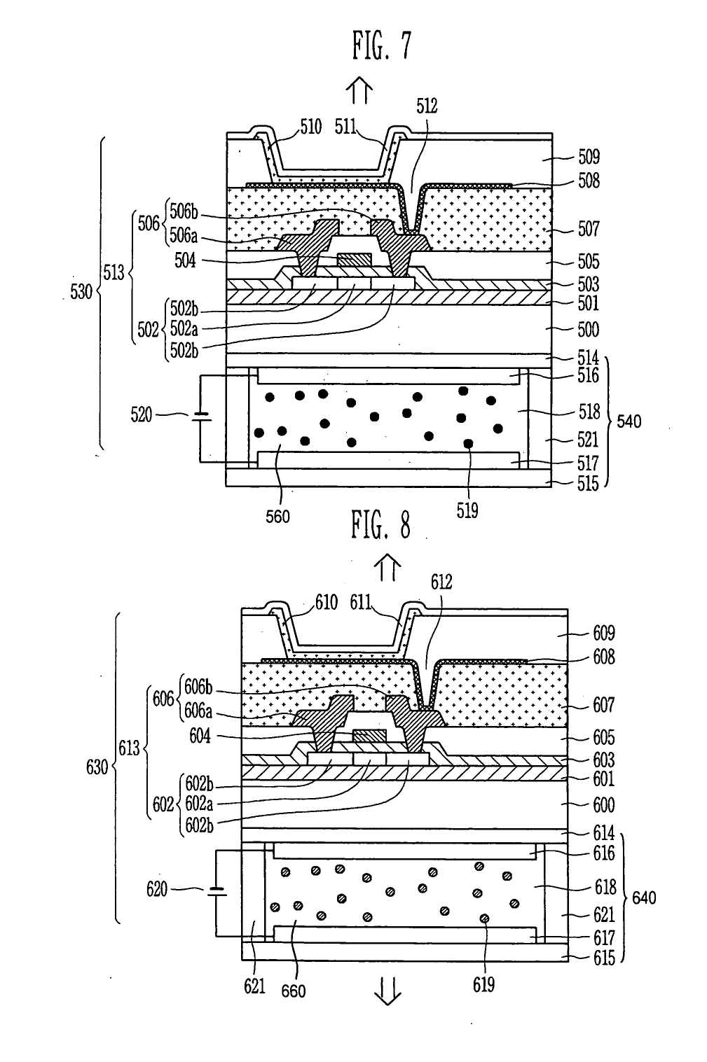

A control unit 420 is formed between first transparent electrode 416 and second transparent electrode 417. Control unit 420 is formed with a switch (not shown), which switches an electric conductive direction. Therefore, by operating the switch, first transparent electrode 416 conducts negative (−) current and second transparent electrode 417 conducts positive (+) current so that chemical reaction is generated in electrochromic layer 460. Detailed description of chemical reaction will be described with reference to FIGS. 7 and 8.

Further, a sealing member (not shown) is formed around first transparent substrate 414 and second transparent substrate 415 to prevent electrolyte 418 from being leak to the outside of first and second transparent substrates 414 and 415 and to bond first transparent substrate 414 and second transparent 415. The distance between first transparent substrate 414 and second transparent substrate 415 is in the range of approximately 10 μm to approximately 100 μm.

In other words, if voltage is not applied between first transparent electrode 416 and second transparent electrode 417, electrolyte 418 containing coloring agent 419 is transparent so that OLED 430 according to the principles of the present invention emits light from two sides of OLED 430.

FIGS. 7 and 8 are a schematic sectional view illustrating a method of driving an OLED constructed as a third embodiment of the principles of the present invention. For the sake of convenience, detailed description of the same elements as those of FIG. 3 will be omitted. In particular, detailed description of a transparent thin film transistor and materials of the transparent thin film transistor will be omitted.

FIG. 7 is a schematic sectional view illustrating a state that a voltage is applied to organic light emitting display 530 constructed as the third embodiment of the principles of the present invention.

Referring to FIG. 7, a voltage is applied between first transparent electrode 516 and second transparent electrode 517 by switching electric conductive direction by a switch (not shown) provided on control unit 520. An electrolyte 518 containing a coloring agent 519 changes its own color by oxidation and reduction reactions. Elements are colored by electrochemical reaction inside an electrochromic layer 560 which is a coloring layer.

For example, reviewing compound reaction equations of viologen, as shown in reaction equation 1, is cathode compound reaction equation of a typical viologen derivative. The viologen is a transparent state as Bipm²⁺ in an original state, but if voltage is applied to the viologen, reduction reaction is generated in electrochromic layer 560 to change the state of the viologen into Bipm⁺ state, thereby indicating a deep black. Likewise, if oxidation reaction is generated in the electrochromic layer, the viologen changes its color from a deep black to a transparent state.

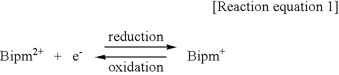

As can be seen from chemical equation 1, if the viologen is applied with a voltage, the viologen reacts as a chemical equation 1 to change its color from a transparent state to a deep black. In chemical equation 1, each of R₁ and R₂ indicates phenyl group or alkyl group having 1 to 10 carbon atoms. Likewise, if oxidation reaction is generated, the viologen changes its color from a deep black to a transparent state.

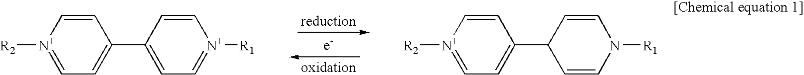

That is, if a voltage is applied between first transparent electrode 516 and second transparent electrode 517, when reduction reaction is generated in electrochromic layer 560, electrochromic layer 560 changes its color from a transparent state to a deep black to serve as a black matrix so that organic light emitting display 530 constructed according to the pinciples of the present invention can emit light from front side of organic light emitting display 530. Also, when oxidation reaction is generated in electrochromic layer 560, electrochromic layer 560 changes its color from a deep black to a transparent state so that OLED 530 constructed according to the principles of the present invention can emit light from two side of OLED 530.

FIG. 8 is a schematic sectional view illustrating another state that a voltage is applied to organic light emitting display 630 constructed as the third embodiment of the principles of the present invention.

Referring to FIG. 8, voltage larger than the voltage applied in FIG. 5 is applied between first transparent electrode 616 and second transparent electrode 617 by switching electric conductive direction by a switch (not shown) provided on control unit 620.

A reaction equation 2 is cathode compound reaction equation of viologen derivative. The viologen applied with a voltage becomes Bipm⁺ state to indicate a deep black, but if a voltage larger than the voltage that renders the viologen to become Bipm⁺ state is applied to the viologen, the viologen changes its color to a light black. Likewise, if oxidation reaction is generated, the viologen changes its color from a deep black to a light black.

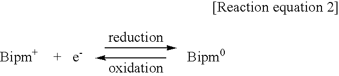

As can be seen from a chemical equation 2, if the viologen is applied with the larger voltage, the viologen reacts as a chemical equation 2 to change its color from a deep black to a light black. In the chemical equation 2, each of R₁ and R₂ indicates phenyl group or alkyl group having 1 to 10 carbon atoms. Likewise, if oxidation reaction is generated, the viologen changes its color from a light black to a deep black.

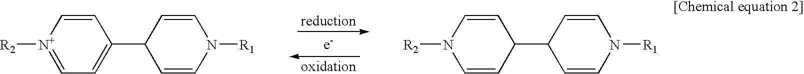

That is, if the larger voltage is applied between first transparent electrode 616 and second transparent electrode 617, when reduction reaction is generated in electrochromic layer 660, electrochromic layer 660 changes its color from a deep black to a light black to indicate gray tone. Also, when oxidation reaction is generated in electrochromic layer 660, electrochromic layer 660 changes its color from a light black to a deep black to make front side emission.

As another example, a reaction equation 3 is anode compound reaction equation of metallocene. In the reaction equation 3, M indicates a metal.

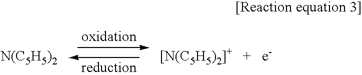

As described above, coloring agent 619 of electrochromic layer 660 may contain many substances such as aromatic amine, oxidation reduction complex, phtalocyanine, heterocyclic compound, fluoran, styryl, anthraquinone, and phtalicdiester. Electrolyte 618 may contain aqueous or non-aqueous liquid (electrolyte) and semi-solid (high polymer electrolyte).

That is, organic light emitting display 630 according to the principles of the present invention controls the voltage applied to electrochromic layer 660, enabling to freely display an image in front side emission or two side emission.

The organic light emitting display according to the principles of the present invention is further provided with an optical sensor or a voice sensor, enabling to freely display an image depending on light or voice.

In above-described embodiments, the TFT and the aperture overlap each other. The TFT and the aperture, however, may not overlap each other. Also, according to the above-described embodiments, the coplanar TFT has been described. The present invention, however, can be applied to a reverse coplanar structure, a staggered structure, and a reverse staggered structure.

As described above, the present invention relates to a flat panel display and an organic light emitting display which maintains an opaque state depending on a user's desired time point or an established time point, while maintaining a transparent state at ordinary times, by forming a transparent two side emission panel and a control unit on the lower portion of the transparent two side emission panel, enabling to freely display an image in two side or one side and to improve image illuminance.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A flat panel display (FPD) comprising:
a transparent two side emission panel; and
a control unit provided on at least one side of the transparent two side emission panel to control an array of liquid crystal layers depending on voltage applied to the liquid crystal layers and control transmission of light by a first polarizing member and a second polarizing member.

2. The FPD as claimed in claim 1, comprised of the control unit comprising:
a first polarizing member connected to a side of the transparent two side emission panel;
a first substrate connected to the first polarizing member;
a first transparent electrode connected to the first substrate;
a liquid crystal layer connected to the first transparent electrode;
a second transparent electrode connected to the liquid crystal layer;
a second substrate connected to the second transparent electrode; and
a second polarizing member connected to the lower portion of the second substrate.

3. The FPD as claimed in claim 2, further comprising a controller for applying voltage to the first transparent electrode or the second transparent electrode in the control unit.

4. An organic light emitting display (OLED) comprising:
an organic light emitting display unit including at least one organic light emitting element formed on one side of a transparent substrate; and
a control unit formed on the other side of the organic light emitting display unit to control intensity of light of the organic light emitting display unit, by controlling an array of liquid crystal layers depending on voltage applied to the liquid crystal layers and controlling transmission of light by a first polarizing member and a second polarizing member.

5. The OLED as claimed in claim 4, comprised of the control unit comprising:
a first polarizing member connected to a side of the organic light emitting element;
a first substrate connected to the first polarizing member;
a first transparent electrode connected to the first substrate;
a liquid crystal layer connected to the first transparent electrode;
a second transparent electrode connected to the liquid crystal layer;
a second substrate connected to the second transparent electrode; and
a second polarizing member connected to the lower portion of the second substrate.

6. The OLED as claimed in claim 5, further comprising a controller for applying voltage to the first transparent electrode or the second transparent electrode in the control unit.

7. The OLED as claimed in claim 6, comprised of the controller being manually driven.

8. The OLED as claimed in claim 6, comprised of the controller being automatically controlled depending on intensity of light from the external region.

9. The OLED as claimed in claim 4, comprised of the organic light emitting display unit comprising at least one transparent thin film transistor for driving the organic light emitting element.

10. The OLED as claimed in claim 9, comprised of the transparent thin film transistor comprising a transparent semiconductor layer, a gate electrode and source and drain electrodes, which are formed on the transparent substrate.

11. The OLED as claimed in claim 11, comprised of the transparent semiconductor layer being made from wide band semiconductor substances having a band gap larger than approximately 3.0 eV.

12. The OLED as claimed in claim 11, comprised of the wide band semiconductor substances being made from ZnO, ZnSnO, GaSnO, GaN or SiC.

13. The OLED as claimed in claim 11, comprising the gate electrode and the source/drain electrodes being a transparent electrode.

14. The OLED as claimed in claim 11, comprised of the gate electrode and the source/drain electrode being made from substances being both electrically conductive and optically transparent within said band gap.

15. The OLED as claimed in claim 14, comprised of the substances being made from at least one selected from group consisting of indium tin oxide (ITO), indium zinc oxide (IZO), and indium tin zinc oxide (ITZO) and translucent metals, etc.

16. An organic light emitting display (OLED) comprising:
a transparent organic light emitting display unit including at least one organic light emitting element formed on one side of a transparent substrate; and
an electrophoretic device formed on an opposite side of the organic light emitting display unit disposed to control a position of a plurality of charged particles in dependence upon a voltage applied to the electrophoretic device and shield or transmit light emitted from the organic light emitting display unit.

17. The OLED as claimed in claim 16, comprised of the electrophoretic device comprising:
a first transparent substrate connected to one side of the transparent organic light emitting display unit;
a second transparent substrate spaced apart from the first transparent substrate and facing the first transparent substrate;
a pair of first transparent electrodes respectively mounted on the sides of the first and second transparent substrates;
a pair of second transparent electrodes respectively mounted on the ends of the first and second transparent substrates; and
the plurality of charged particles dispersed into a solvent, which serves as a light shielding layer and is filled between the first and second transparent substrates.

18. The OLED as claimed in claim 17, comprised of the charged particles being black and being made from inorganic pigment, organic pigment, carbon black, or resin containing the material.

19. The OLED as claimed in claim 17, comprised of the solvent being made from a transparent non-polar solvent such as isoparaffin, silicon oil, xylene, and toluene.

20. An organic light emitting display (OLED) comprising:
a transparent organic light emitting display unit including at least one organic light emitting element formed on one side of a transparent substrate; and
an electrochromic device formed on an opposite side of the organic light emitting display unit disposed to change a color of an electrochromic layer disposed in the electrochromic device in dependence upon a voltage applied to the electrochromic device and to shield or transmit light emitted from the organic light emitting display unit.

21. The OLED as claimed in claim 20, comprised of the electrochromic device comprising:
a first transparent substrate and a second transparent substrate in opposition to each other on other side of the transparent organic light emitting display unit and spaced apart from each other;
a first transparent electrode and a second transparent electrode respectively formed on the internal sides of the first and second transparent substrates;
the electrochromic layer filled with an electrolyte containing a coloring agent and formed between the first and second transparent electrodes;
a control unit formed between the first and second transparent electrodes.
